(19) United States
(12) Patent Application Publication
(10) Pub. No.: US 2024/0179850 A1
(43) Pub. Date: May 30, 2024

(54) ELECTRONIC DEVICE AND MANUFACTURING METHOD THEREFOR

(71) Applicants: SAMSUNG ELECTRONICS CO., LTD., Suwon-si (KR); BS TECHNICS CO., LTD., Ansan-si (KR); INTOPS CO., LTD., Anyang-si (KR)

(72) Inventors: Chunghyo JUNG, Suwon-si (KR); Chiyoung YOON, Suwon-si (KR); Jungsik CHOI, Siheung-si (KR)

(73) Assignees: SAMSUNG ELECTRONICS CO., LTD., Suwon-si (KR); BS TECHNICS CO., LTD., Ansan-si (KR); INTOPS CO., LTD., Anyang-si (KR)

(21) Appl. No.: 18/432,807

(22) Filed: Feb. 5, 2024

Related U.S. Application Data
(63) Continuation of application No. PCT/KR22/11198, filed on Jul. 29, 2022.

(30) Foreign Application Priority Data
Aug. 5, 2021 (KR) 10-2021-0103137

(51) Int. Cl. H05K 3/34; B23K 1/002; B23K 101/42; H05K 3/10; H05K 3/42

(52) U.S. Cl. CPC H05K 3/3485; B23K 1/002; H05K 3/101; H05K 3/3494; H05K 3/429; B23K 2101/42; H05K 2203/0126; H05K 2203/101

(57) ABSTRACT

An electronic device includes an injection mold including a mounting part and a wiring groove, a plated wiring plated on the wiring groove, and an electronic element mounted on the mounting part and electrically connected to the plated wiring, wherein the plated wiring is plated on an outer region of the injection mold, and the electronic element mounted on the injection mold dispensed on the plated wiring.

### CROSS REFERENCE TO RELATED APPLICATIONS

This application is a continuation of International Application No. PCT/2022/011198, filed on Jul. 29, 2022, which is based on and claims priority to Korean Patent Application No. 10-2021-0103137, filed on Aug. 5, 2021, in the Korean Intellectual Property Office, the disclosures of which are incorporated by reference herein in their entireties.

### BACKGROUND

### 1. Field

The disclosure relates to an electronic device and a manufacturing method thereof.

### 2. Description of the Related Art

An electronic device includes various electronic elements which may be mounted to a printed circuit board. A process of mounting electronic elements to the printed circuit board may be performed by soldering the electronic elements to the printed circuit board and coupling the printed circuit board to an injection mold.

An electronic device had to go through the process of performing soldering on a printed circuit board to mount electronic elements and coupling the printed circuit board to an injection mold. A control of a soldering fillet was required to solder various types and shapes of electronic elements, and a reflow method, which is one of soldering processes, was used for the control of the soldering fillet through photo imageable solder resist (PSR) coating on the printed circuit board.

Recently, with technological development, there has been a technical demand for a slimmer or lighter electronic device to improve portability and convenience for users.

Accordingly, research on a mold direct mount (MDM) structure for mounting electronic elements directly to an injection mold (e.g., a plastic material) in an electronic device has been underway and efforts have been made to reduce an area occupied by a coupling structure of the electronic elements.

### SUMMARY

According to an aspect of the disclosure, an electronic device includes: an injection mold including a mounting part and a wiring groove, a plated wiring plated on the wiring groove, and an electronic element mounted on the mounting part and connected electrically to the plated wiring, wherein the plated wiring is plated on an outer region of the injection mold, and the electronic element is mounted on the injection mold by a solder paste dispensed on the plated wiring.

The injection mold may include a first mounting part and a second mounting part, the first mounting part and the second mounting part are spaced apart from each other, and the electronic element may include a first electronic element provided in the first mounting part and bonded by a first solder paste, and a second electronic element provided in the second mounting part and bonded by a second solder paste having a spreadability different from the first solder paste.

The plated wiring may include a thin-film coated multilayer, the thin-film coated multilayer may include a metal material top layer.

The metal material top layer of the plated wiring may include at least one of gold (Au) and nickel (Ni).

The metal material top layer of the plated wiring may have a thickness between 0.01 μm and 0.05 μm.

The plated wiring may further include a first region to which the electronic element is mounted on, a second region connected to the first region, and a third region distanced farther from the first region than the second region, and the third region having a width less than the width of the second region.

The injection mold may include a curved region and the electronic element may be mounted on the curved region.

The injection mold may communicate from a first surface to a second surface opposite to the first surface and the injection mold may include a via hole having a cross-sectional area of an inner surface, the cross-sectional area increases from the first surface to the second surface, and the plated wiring may cover the inner surface of the via hole and is deposited from the first surface to the second surface through the via hole.

According to an aspect of the disclosure, a method of manufacturing an electronic device includes: depositing plated wiring through laser processing and plating the plated wiring on an injection mold, dispensing a solder paste on the plated wiring, mounting an electronic element to the solder paste, placing an induction heater adjacent to the electronic element, the induction heater may heat the solder paste, and melting the solder paste through the induction heater to mount the electronic element on the injection mold.

The method may further include prior to the placing the induction heater adjacent to the electronic element, rotating the injection mold such that the injection heater faces the electronic element.

The injection mold may include a first mounting part and a second mounting part, and the dispensing the solder paste on the plated wiring may include: dispensing a first solder paste with a preset discharge amount on the first mounting part, and dispensing a second solder paste with a preset discharge amount the second mounting part.

The preset discharge amount of the first solder paste may be different from the preset discharge amount of the second solder paste.

The amount of first solder paste dispensed may be different from the amount of the second solder paste dispensed.

The melting the solder paste may include: melting the first solder paste, melting the second solder paste, and the melting of the first solder paste and the second solder paste may be performed sequentially.

The melting of the first solder paste and the second solder paste may be different from each other in at least one of an induction heating time of the induction heater, induction heating power of the induction heater, or a distance from the solder paste to the induction heater.

According to one or more embodiments, the implementing of an MDM method by forming plated wiring in the injection mold and dispensing a solder paste in the plated wiring may improve spatial efficiency inside the electronic device.

According to one or more embodiments, the thickness of the solder paste may set differently for each of the electronic elements.

According to one or more embodiments, an electronic element may be mounted directly to an injection mold by soldering the electronic element on plated wiring on the injection mold in an induction heating method.

According to one or more embodiments, a design space inside an electronic device may be further secured by reducing an area occupied by a printed circuit board in the electronic device.

According to one or more embodiments, a soldering process of an electronic element may be performed precisely through the dispensing and induction heating of an individual solder paste.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram illustrating an electronic device in a network environment, according to one or more embodiments of the disclosure;

FIG. 2A is a front perspective view of an electronic device according one or more embodiments;

FIG. 2B is a rear perspective view of the electronic device according to one or more embodiments;

FIG. 3 is an exploded perspective view of the electronic device according to one or more embodiments;

FIG. 4A is a plan view of an injection mold of the electronic device according to one or more embodiments;

FIG. 4B is a perspective view of the injection mold of the electronic device according to one or more embodiments;

FIG. 4C is another perspective view of the injection mold of the electronic device according to one or more embodiments;

FIG. 5 is a cross-sectional view of a partial region of the electronic device according to one or more embodiments;

FIG. 6A is an expanded perspective view of the electronic device according to one or more embodiments;

FIG. 6B is a plan view of the electronic device according to one or more embodiments;

FIG. 6C is an expanded perspective view of the electronic device according to one or more embodiments;

FIG. 7 is a cross-sectional view of plated wiring according to one or more embodiments;

FIG. 8 is a flowchart of a method of manufacturing the electronic device according to one or more embodiments;

FIG. 9A is a diagram illustrating a manufacturing operation of the method of manufacturing the electronic device according to one or more embodiments;

FIG. 9B is a diagram illustrating a manufacturing operation of the method of manufacturing the electronic device according to one or more embodiments;

FIG. 9C is a diagram illustrating a manufacturing operation of the method of manufacturing the electronic device according to one or more embodiments;

FIG. 9D is a diagram illustrating a manufacturing operation of the method of manufacturing the electronic device according to one or more embodiments;

FIG. 10 is a flowchart of the method of manufacturing the electronic device according to one or more embodiments;

FIG. 11A is a profile of a temperature of a solder paste with respect to a time of the method of manufacturing the electronic device according to one or more embodiments;

FIG. 11B is a profile of adhesion with respect to an amount of a solder paste of the method of manufacturing the electronic device according to one or more embodiments; and

FIG. 12 is a perspective view of the electronic device according to one or more embodiments.

### DETAILED DESCRIPTION

Hereinafter, embodiments will be described in detail with reference to the accompanying drawings. When describing the embodiments with reference to the accompanying drawings, like reference numerals refer to like elements and a repeated description related thereto will be omitted.

It should be appreciated that the embodiments described herein are example embodiments, and thus, the disclosure is not limited thereto and embodiments may include various modifications, equivalents, and/or alternatives. In connection with the description of the drawings, like reference numerals may be used for similar or related components. It is to be understood that a singular form of a noun corresponding to an item may include one or more of the things unless the relevant context clearly indicates otherwise. As used herein, “A or B”, “at least one of A and B”, “at least one of A or B”, “A, B or C”, “at least one of A, B and C”, and “A, B, or C,” each of which may include any one of the items listed together in the corresponding one of the phrases, or all possible combinations thereof. Terms such as “first”, “second”, or “first” or “second” may simply be used to distinguish the component from other components in question, and do not limit the components in other aspects (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., by wire), wirelessly, or via a third element.

As used in connection with embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. According to one or more embodiments, the module may be implemented in a form of an application-specific integrated circuit (ASIC).

One or more embodiments of the present disclosure as set forth herein may be implemented as software (e.g., the program 120) including one or more instructions that are stored in a storage medium (e.g., an internal memory 136 or an external memory 138) that is readable by a machine (e.g., an electronic device). A processor of the machine (e.g., an electronic device) may invoke at least one of the one or more instructions stored in the storage medium and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

A method according to one or more embodiments of the disclosure may be included and provided in a computer program product. The computer program product may be traded as a product between a seller and a buyer. The computer program product may be distributed in the form of a machine-readable storage medium (e.g., a compact disc read-only memory (CD-ROM)), or be distributed (e.g., downloaded or uploaded) online via an application store (e.g., PlayStore™), or between two user devices (e.g., smartphones) directly. If distributed online, at least part of the computer program product may be temporarily generated or at least temporarily stored in the machine-readable storage medium, such as memory of the manufacturer's server, a server of the application store, or a relay server.

According to one or more embodiments, each component (e.g., a module or a program) of the above-described components may include a single entity or multiple entities, and some of the multiple entities may be separately disposed in different components. According to one or more embodiments, one or more of the above-described components may be omitted, or one or more other components may be added. Alternatively or additionally, a plurality of components (e.g., modules or programs) may be integrated into a single component. In such a case, according to an embodiment, the integrated component may still perform one or more functions of each of the components in the same or similar manner as they are performed by a corresponding one among the components before the integration. According to one or more embodiments, operations performed by the module, the program, or another component may be carried out sequentially, in parallel, repeatedly, or heuristically, or one or more of the operations may be executed in a different order or omitted, or one or more other operations may be added.

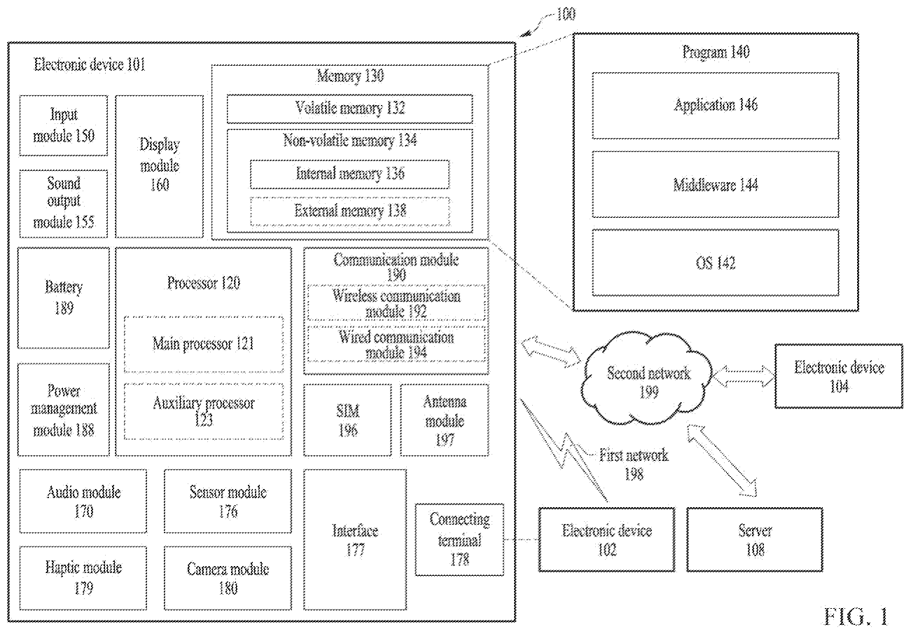

FIG. 1 is a block diagram illustrating an electronic device 101 in a network environment 100, according to various embodiments. Referring to FIG. 1, an electronic device 101 in a network environment 100 may communicate with an electronic device 102 via a first network 198 (e.g., a short-range wireless communication network), or communicate with at least one of an electronic device 104 or a server 108 via a second network 199 (e.g., a long-range wireless communication network). According to one or more embodiments, the electronic device 101 may communicate with the electronic device 104 via the server 108. According to one or more embodiments, the electronic device 101 may include a processor 120, a memory 130, an input module 150, a sound output module 155, a display module 160, an audio module 170, and a sensor module 176, an interface 177, a connecting terminal 178, a haptic module 179, a camera module 180, a power management module 188, a battery 189, a communication module 190, a subscriber identification module (SIM) 196, or an antenna module 197. At least one (e.g., the connecting terminal 178) of the above components may be omitted from the electronic device 101, or one or more other components may be added in the electronic device 101. Some (e.g., the sensor module 176, the camera module 180, or the antenna module 197) of the components may be integrated as a single component (e.g., the display module 160).

The processor 120 may execute software (e.g., a program 140) to control at least one other component (e.g., a hardware or software component) of the electronic device 101 connected to the processor 120 and may perform various data processing or computation. According to one or more embodiments, as at least a part of data processing or computation, the processor 120 may store a command or data received from another component (e.g., the sensor module 176 or the communication module 190) in a volatile memory 132, process the command or the data stored in the volatile memory 132, and store resulting data in a non-volatile memory 134. According to one or more embodiments, the processor 120 may include a main processor 121 (e.g., a central processing unit (CPU) or an application processor (AP)) or an auxiliary processor 123 (e.g., a graphics processing unit (GPU), a neural processing unit (NPU), an image signal processor (ISP), a sensor hub processor, or a communication processor (CP)) that is operable independently of, or in conjunction with the main processor 121. For example, when the electronic device 101 includes the main processor 121 and the auxiliary processor 123, the auxiliary processor 123 may be adapted to consume less power than the main processor 121 or to be specific to a specified function. The auxiliary processor 123 may be implemented separately from the main processor 121 or as a part of the main processor 121.

The auxiliary processor 123 may control at least some of functions or states related to at least one (e.g., the display module 160, the sensor module 176, or the communication module 190) of the components of the electronic device 101 instead of the main processor 121 while the main processor 121 is in an inactive (e.g., sleep) state or along with the main processor 121 while the main processor 121 is an active state (e.g., executing an application). According to one or more embodiments, the auxiliary processor 123 (e.g., an ISP or a CP) may be implemented as a portion of another component (e.g., the camera module 180 or the communication module 190) that is functionally related to the auxiliary processor 123. According to one or more embodiments, the auxiliary processor 123 (e.g., an NPU) may include a hardware structure specified for artificial intelligence (AI) model processing. An AI model may be generated by machine learning. The machine learning may be performed by, for example, the electronic device 101, in which artificial intelligence is performed, or performed via a separate server (e.g., the server 108). Learning algorithms may include, but are not limited to, supervised learning, unsupervised learning, semi-supervised learning, or reinforcement learning. The AI model may include a plurality of artificial neural network layers. An artificial neural network may include, but not limited to, a deep neural network (DNN), a convolutional neural network (CNN), a recurrent neural network (RNN), a restricted Boltzmann machine (RBM), a deep belief network (DBN), a bidirectional recurrent deep neural network (BRDNN), and a deep Q-network or a combination of two or more thereof but is not limited thereto. The AI model may additionally or alternatively include a software structure other than the hardware structure.

The memory 130 may store various pieces of data used by at least one component (e.g., the processor 120 or the sensor module 176) of the electronic device 101. The various pieces of data may include, but not limited to, software (e.g., the program 140) and input data or output data for a command related thereto. The memory 130 may include the volatile memory 132 or the non-volatile memory 134.

The program 140 may be stored as software in the memory 130 and may include, but not limited to, an operating system (OS) 142, middleware 144, or an application 146.

The input module 150 may receive, from outside (e.g., a user) the electronic device 101, a command or data to be used by another component (e.g., the processor 120) of the electronic device 101. The input module 150 may include, but not limited to, a microphone, a mouse, a keyboard, a key (e.g., a button), or a digital pen (e.g., a stylus pen).

The sound output module 155 may output a sound signal to the outside of the electronic device 101. The sound output module 155 may include, but not limited to, a speaker or a receiver. The speaker may be used for general purposes, such as playing multimedia or playing a recording. The receiver may be used to receive an incoming call. According to one or more embodiments, the receiver may be implemented separately from the speaker or as a part of the speaker.

The display module 160 may visually provide information to the outside (e.g., a user) of the electronic device 101. The display module 160 may include, but not limited to, a control circuit for controlling a display, a hologram device, or a projector and control circuitry to control a corresponding one of the display, the hologram device, and the projector. According to one or more embodiments, the display device 160 may include a touch sensor adapted to sense a touch or a pressure sensor adapted to measure the intensity of a force incurred by the touch.

The audio module 170 may convert a sound into an electric signal or vice versa. According to one or more embodiments, the audio module 170 may obtain the sound via the input module 150 or may output the sound via the sound output module 155 or an external electronic device (e.g., an electronic device 102 such as a speaker or a headphone) directly or wirelessly connected to the electronic device 101.

The sensor module 176 may detect an operational state (e.g., power or temperature) of the electronic device 101 or an environmental state (e.g., a state of a user) external to the electronic device 101 and may generate an electric signal or data value corresponding to the detected state. According to one or more embodiments, the sensor module 176 may include, but not limited to, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used by the electronic device 101 to couple with the external electronic device (e.g., the electronic device 102) directly (e.g., by wire) or wirelessly. According to one or more embodiments, the interface 177 may include, but not limited to, a high-definition multimedia interface (HDMI), a universal serial bus (USB) interface, a secure digital (SD) card interface, or an audio interface.

The connecting terminal 178 may include a connector via which the electronic device 101 may be physically connected to an external electronic device (e.g., the electronic device 102). According to one or more embodiments, the connecting terminal 178 may include, but not limited to, an HDMI connector, a USB connector, an SD card connector, or an audio connector (e.g., a headphone connector).

The haptic module 179 may convert an electric signal into a mechanical stimulus (e.g., a vibration or a movement) or an electrical stimulus, which may be recognized by a user via their tactile sensation or kinesthetic sensation. According to one or more embodiments, the haptic module 179 may include, but not limited to, a motor, a piezoelectric element, or an electric stimulator.

The camera module 180 may capture a still image and moving images. According to one or more embodiments, the camera module 180 may include one or more lenses, image sensors, ISPs, or flashes.

The power management module 188 may manage power supplied to the electronic device 101. According to one or more embodiments, the power management module 188 may be implemented as, but not limited to, at least a part of a power management integrated circuit (PMIC).

The battery 189 may supply power to at least one component of the electronic device 101. According to one or more embodiments, the battery 189 may include, but not limited to, a primary cell that is not rechargeable, a secondary cell that is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more CPs that are operable independently from the processor 120 (e.g., an AP) and that support direct (e.g., wired) communication or wireless communication. According to one or more embodiments, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module, or a power line communication (PLC) module). At least of these communication modules may communicate with the external electronic device 104 via the first network 198 (e.g., a short-range communication network, such as Bluetooth™, wireless-fidelity (Wi-Fi) direct, or IR data association (IrDA)) or the second network 199 (e.g., a long-range communication network, such as a legacy cellular network, a 5G network, a next-generation communication network, the Internet, or a computer network (e.g., a LAN or a wide area network (WAN)). These various types of communication modules may be implemented as a single component (e.g., a single chip) or may be implemented as multi-components (e.g., multi-chips) separate from each other. The wireless communication module 192 may identify and authenticate the electronic device 101 in a communication network, such as the first network 198 or the second network 199, using subscriber information (e.g., international mobile subscriber identity (IMSI)) stored in the SIM 196.

The wireless communication module 192 may support a 5G network after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., a mm Wave band) to achieve, e.g., a high data transmission rate. The wireless communication module 192 may support various technologies for securing performance on a high-frequency band, such as, e.g., beamforming, massive multiple-input and multiple-output (MIMO), full dimensional MIMO (FD-MIMO), an array antenna, analog beam-forming, or a large-scale antenna. The wireless communication module 192 may support various requirements specified in the electronic device 101, an external electronic device (e.g., the electronic device 104), or a network system (e.g., the second network 199). According to one or more embodiments, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to one or more embodiments, the antenna module 197 may include an antenna including a radiating element including a conductive material or a conductive pattern formed in or on a substrate (e.g., a printed circuit board (PCB)). According to one or more embodiments, the antenna module 197 may include a plurality of antennas (e.g., array antennas). At least one antenna appropriate for a communication scheme used in a communication network, such as the first network 198 or the second network 199, may be selected by the communication module 190 from the plurality of antennas. The signal or power may be transmitted or received between the communication module 190 and the external electronic device via the at least one selected antenna. According to one or more embodiments, another component (e.g., a radio frequency integrated circuit (RFIC)) other than the radiating element may be additionally formed as a part of the antenna module 197.

According to one or more embodiments, the antenna module 197 may form a mmWave antenna module. According to one or more embodiments, the mm Wave antenna module may include a PCB, an RFIC disposed on a first surface (e.g., a bottom surface) of the PCB or adjacent to the first surface and capable of supporting a designated a high-frequency band (e.g., the mm Wave band), and a plurality of antennas (e.g., array antennas) disposed on a second surface (e.g., a top or a side surface) of the PCB, or adjacent to the second surface and capable of transmitting or receiving signals in the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to one or more embodiments, commands or data may be transmitted or received between the electronic device 101 and the external electronic device 104 via the server 108 coupled with the second network 199. Each of the external electronic devices (e.g., the electronic device 102 or 104) may be a device of the same type as or a different type from the electronic device 101. According to one or more embodiments, all or some of operations to be executed by the electronic device 101 may be executed at one or more external electronic devices (e.g., the external devices 102 and 104, and the server 108). If the electronic device 101 needs to perform a function or a service automatically, or in response to a request from a user or another device, the electronic device 101, instead of, or in addition to, executing the function or the service, may request the one or more external electronic devices to perform at least part of the function or service. The one or more external electronic devices receiving the request may perform the at least part of the function or service, or an additional function or an additional service related to the request and may transfer a result of the performance to the electronic device 101. The electronic device 101 may provide the result, with or without further processing the result, as at least part of a response to the request. Cloud computing, distributed computing, mobile edge computing (MEC), or client-server computing technology may be used, for example. The electronic device 101 may provide ultra-low-latency services using, e.g., distributed computing or MEC. According to one or more embodiments, the external electronic device 104 may include an Internet-of-things (IOT) device. The server 108 may be an intelligent server using machine learning and/or a neural network. According to one or more embodiments, the external electronic device 104 or the server 108 may be included in the second network 199. The electronic device 101 may be applied to intelligent services (e.g., smart home, smart city, smart car, or healthcare) based on 5G communication technology or IoT-related technology.

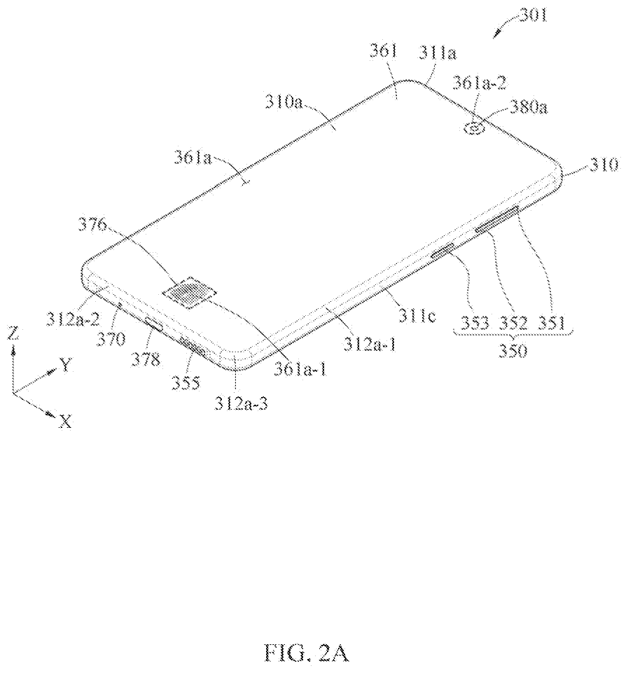

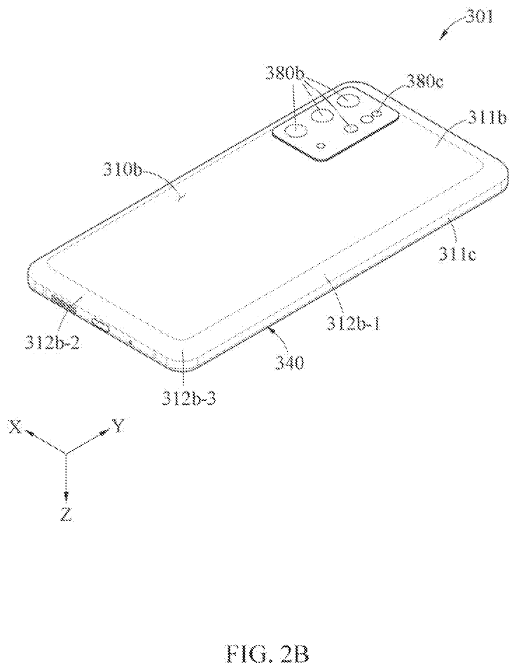

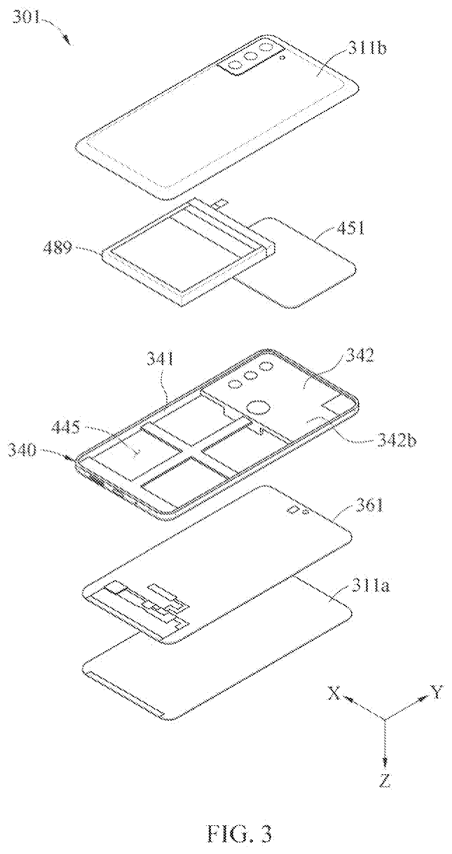

FIG. 2A is a front perspective view of an electronic device according to one or more embodiments, FIG. 2B is a rear perspective view of the electronic device according to one or more embodiments, and FIG. 3 is an exploded perspective view of the electronic device according to one or more embodiments.

Referring to FIGS. 2A, 2B, and 3, an electronic device 301 (e.g., the electronic device 101 of FIG. 1) according to one or more embodiments may include a housing 310 having a front surface 310a, a rear surface 310b, and a side surface 311c surrounding an internal space between the front surface 310a and the rear surface 310b.

According to one or more embodiments, the housing 310 may form an exterior of the electronic device 301 and may accommodate, protect, and support internal components. According to one or more embodiments, the housing 310 may form a front plate 311a forming the front surface 310a, a rear plate 311b forming the rear surface 310b, and the side surface 311c surrounding a space between the front plate 311a and the rear plate 311b and may include a side housing 341 including an injection mold.

According to one or more embodiments, the front surface 310a of the electronic device 301 may be formed by the front plate 311a of which at least a portion is substantially transparent. The front plate 311a may include a polymer plate or a glass plate including at least one coating layer. According to one or more embodiments, the rear surface 310b of the electronic device 301 may be formed by the rear plate 311b that is substantially opaque. The rear plate 311b may be formed of coated or tinted glass, ceramic, polymer, metal (e.g., aluminum, stainless steel, or magnesium), or a combination thereof. According to one or more embodiments, the side surface 311c of the electronic device 301 may be coupled to the front plate 311a and the rear plate 311b and may be formed by an injection mold 340 including at least one of metal and polymer.

According to one or more embodiments, the injection mold 340 may be between the front plate 311a and the rear plate 311b, and the rear plate 311b and the injection mold 340 may be integrated seamlessly. According to one or more embodiments, the rear plate 311b and the injection mold 340 may be formed of substantially the same material (e.g., aluminum).

According to one or more embodiments, the front plate 311a may include a plurality of first periphery areas 312a-1 that are rounded in a direction from at least one area of the front surface 310a toward the rear plate 311b and extend in one direction (e.g., a + or −X-axis direction), a plurality of second periphery areas 312a-2 that are rounded in the direction from at least one area of the front surface 310a toward the rear plate 311b and extend in the other direction (e.g., a + or −Y-axis direction), and a plurality of third periphery areas 312a-3 that are rounded in the direction from at least one area of the front surface 310a toward the rear plate 311b and between the plurality of first periphery areas 312a-1 and the plurality of second periphery areas 312a-2.

According to one or more embodiments, the rear plate 311b may include a plurality of fourth periphery areas 312b-1 that are rounded in a direction from at least one area of the rear surface 310b toward the front plate 311a and extend in one direction (e.g., a + or − X-axis direction), a plurality of fifth periphery areas 312b-2 that are rounded in the direction from at least one area of the rear surface 310b toward the front plate 311a and extend in the other direction (e.g., a + or − Y-axis direction), and a plurality of sixth periphery areas 312b-3 that are rounded in the direction from at least one area of the rear surface 310b toward the front plate 311a and between the plurality of fourth periphery areas 312b-1 and the plurality of fifth periphery areas 312b-2.

According to one or more embodiments, the injection mold 340 may surround at least a portion of the internal space between the front surface 310a and the rear surface 310b, and at least a portion of the injection mold 340 may be formed of a conductive material. According to one or more embodiments, the injection mold 340 may include a flat housing 342, which is a flat surface region, and the side housing 341, which is a side surface region. According to one or more embodiments, the injection mold 340 may have a curved region or a 3D structure. According to one or more embodiments, the injection mold 340 may be formed as one body through mold injection, and the injection mold 340 may be implemented only by the side housing 341 or may have a structure coupling the side housing 341 to the flat housing 342 that are separately injected.

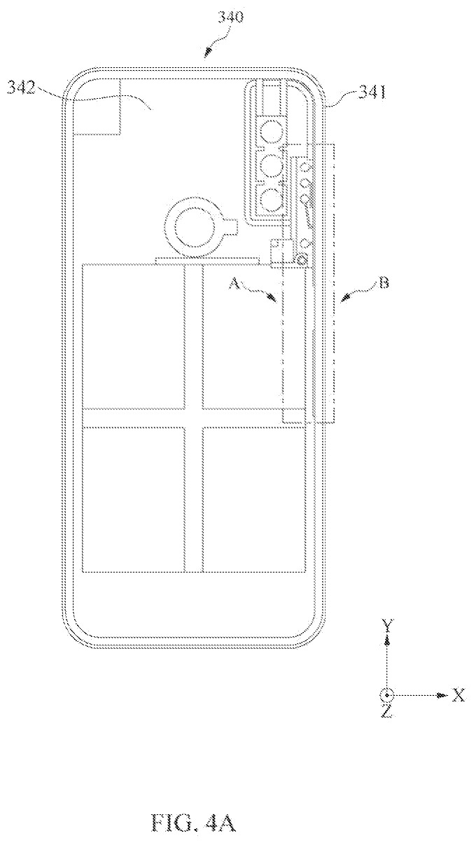

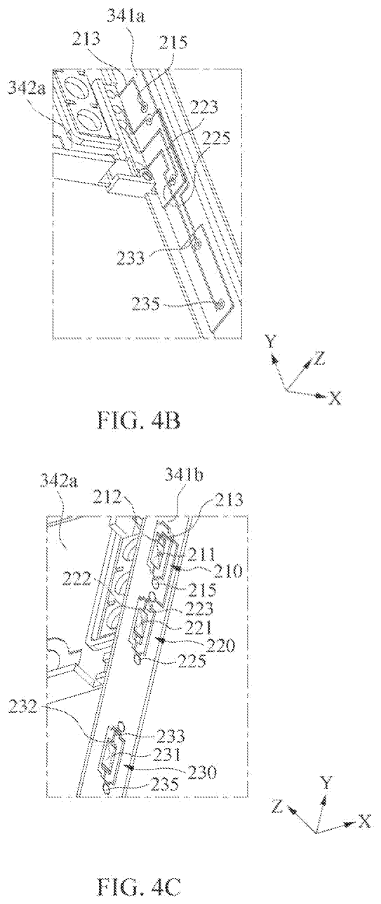

According to one or more embodiments, at least one of a sound increase button 351, a sound decrease button 352, and a power button 353 may be formed on the side surface 311c of the housing 310, and, in this case, electronic elements (e.g., electronic elements 211, 221, and 231 of FIG. 4) corresponding respectively to a plurality of buttons 350 may be on the side housing 340.

According to one or more embodiments, the electronic device 301 may include a display 361 (e.g., the display module 160 of FIG. 1). According to one or more embodiments, the display 361 may be positioned on the front surface 310a. According to one or more embodiments, the display 361 may be exposed through at least a portion (e.g., the plurality of first periphery areas 312a-1, the plurality of second periphery areas 312a-2, and the plurality of third periphery areas 312a-3) of the front plate 311a. According to one or more embodiments, the display 361 may have a shape that is substantially the same as the shape of an outer edge of the front plate 311a. According to one or more embodiments, the periphery of the display 361 may substantially coincide with the outer edge of the first plate 311a. In an embodiment, the display 361 may include at least one or more of a touch-sensing circuit, a pressure sensor for sensing an intensity (pressure) of a touch, and a digitizer for detecting a magnetic-type stylus pen.

According to one or more embodiments, the display 361 may include a screen display area 361a that is visually exposed and displays content through a pixel or a plurality of cells. According to one or more embodiments, the screen display area 361a may include at least one or more of a sensing area 361a-1 and a camera area 361a-2. The sensing area 361a-1 may overlap with at least a portion of the screen display area 361a. The sensing area 361a-1 may allow transmission of an input signal related to a sensor module 376 (e.g., the sensor module 176 of FIG. 1). The sensing area 361a-1 may display content, such that the screen display area 361a that does not overlap with the sensing area 361a-1. For example, the sensing area 361a-1 may display the content while the sensor module 376 is not operating. The camera area 361a-2 may overlap at least one area of the screen display area 361a. The camera area 361a-2 may allow transmission of an optical signal related to first camera modules 380a and 380b (e.g., the camera module 180 of FIG. 1). The camera area 361a-2 may display content, such that the screen display area 361a that does not overlap the camera area 361a-2. For example, the camera area 361a-2 may display the content while the first camera modules 380a and 380b are not operating.

According to one or more embodiments, the electronic device 301 may include an audio module 370 (e.g., the audio module 170 of FIG. 1). The audio module 370 may obtain a sound from the outside of the electronic device 301. For example, the audio module 370 may be positioned on the side surface 311c of the housing 310. According to one or more embodiments, the audio module 370 may obtain a sound through at least one hole.

According to one or more embodiments, the electronic device 301 may include the sensor module 376. The sensor module 376 may sense a signal applied to the electronic device 301. The sensor module 376 may be positioned on the front surface 310a of the electronic device 301. The sensor module 376 may form the sensing area 361a-1 in at least a portion of the screen display area 361a. The sensor module 376 may receive an input signal transmitted through the sensing area 361a-1 and generate an electrical signal based on the received input signal. For example, the input signal may have a designated physical quantity (e.g., heat, light, temperature, sound, pressure, or ultrasound). As another example, the input signal may include a signal related to biometric information (e.g., a fingerprint, a voice, and the like) of a user.

According to one or more embodiments, the electronic device 301 may include the camera modules 380a and 380b (e.g., the camera module 180 of FIG. 1). According to one or more embodiments, the camera modules 380a and 380b may include a first camera module 380a, a second camera module 380b, and a flash 380c. According to one or more embodiments, the first camera module 380a may be arranged to be exposed through the front surface 310a of the housing 310, and the second camera module 380b and the flash 380c may be arranged to be exposed through the rear surface 310b of the housing 310. According to one or more embodiments, at least a portion of the first camera module 380a may be in the housing 310 to be covered through the display 361. According to one or more embodiments, the first camera module 380a may receive an optical signal transmitted through the camera area 361a-2. According to one or more embodiments, the second camera module 380b may include a plurality of cameras (e.g., dual cameras, triple cameras, or quad cameras). According to one or more embodiments, the flash 380c may include a light-emitting diode or a xenon lamp.

According to one or more embodiments, the electronic device 301 may include a sound output module 355 (e.g., the sound output module 155 of FIG. 1). The sound output module 355 may output sound to the outside of the electronic device 301. The sound output module 355 may output sound to the outside of the electronic device 301 through one or more holes formed on the side surface 311c of the housing 310.

According to one or more embodiments, the electronic device 301 may include an input module 350 (e.g., the input module 150 of FIG. 1). The input module 350 may receive a manipulation signal from a user. The input module 350 may include at least one key input device arranged to be exposed on the side surface 311c of the housing 310.

According to one or more embodiments, the electronic device 301 may include a connecting terminal 378 (e.g., the connecting terminal 178 of FIG. 1 According to one or more embodiments, the connecting terminal 378 may be on the side surface 311c. For example, when the electronic device 301 is viewed in one direction (e.g., the +Y-axis direction of FIG. 2A), the connecting terminal may be on a central portion of the side surface 311c and a sound output module 355 may be in a direction (e.g., a right direction) based on the connecting terminal 378.

According to one or more embodiments, the electronic device 301 may include a PCB 451 and a battery 489 (e.g., the battery 189 of FIG. 1). According to one or more embodiments, the PCB 451 may be accommodated in the flat housing 342 of the injection mold 340, and the battery 489 may be accommodated in a battery slot 445 of the injection mold 340.

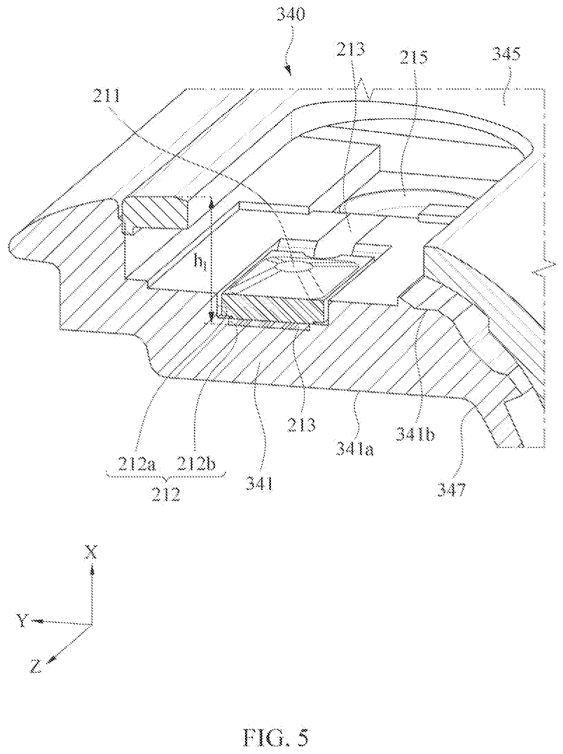

According to one or more embodiments, a processor (e.g., the processor 120 of FIG. 1) may be on the PCB 451. The processor may include, for example, one or more of a CPU, an AP, an image signal processor, a sensor hub processor, and a communication processor. According to one or more embodiments, a wireless communication circuit (e.g., the wireless communication module 192 of FIG. 1) may be on the PCB 451. The wireless communication circuit may perform communication with an external device (e.g., the electronic device 104 of FIG. 1). The electronic device 301 may include an antenna structure (e.g., the antenna module 197 of FIG. 1 and an antenna structure 50 of FIG. 5), and the wireless communication circuit may be electrically connected to the antenna structure.

FIG. 4A is a plan view of an injection mold of the electronic device according to one or more embodiments, FIG. 4B is a perspective view of the injection mold of the electronic device according to one or more embodiments, and FIG. 4C is another perspective view of the injection mold of the electronic device according to one or more embodiments.

FIG. 4B is the perspective view of the injection mold 340 of FIG. 4A in a direction A illustrated in FIG. 4A, and FIG. 4C is the perspective view of the injection mold 340 of FIG. 4A in a direction B illustrated in FIG. 4A.

Referring to FIG. 4A, FIG. 4B, FIG. 4C, the injection mold 340 according to one or more embodiments may include the flat housing 342 and the side housing 341, and the electronic device 301 may include plated wiring 213 and the electronic element 211 that are positioned on the injection mold 340.

According to one or more embodiments, the flat housing 342 may be extended in a horizontal direction (e.g., a horizontal direction with an X-Y plane) with the front plate 311a and the rear plate 311b. The flat housing 342 may accommodate and support at least one component inside the electronic device 301, such as the PCB 451. The flat housing 342 may include a first surface 342a facing a direction of the front plate 311a and a second surface (e.g., a second surface 342b of FIG. 3) facing a direction of the rear plate 311b.

According to one or more embodiments, the side housing 341 may protect a side surface between the front plate 311a and the rear plate 311b and may be extended in a perpendicular direction (e.g., a +/−Z-axis direction) to the front plate 311a and the rear plate 311b. The side housing 341 may include an inner side surface 341a that is toward the inside of the electronic device 301 or the injection mold 340 and facing an inward direction and an outer side surface 341b that is toward the outside of the electronic device 301 or the injection mold 340 and facing an outward direction.

According to one or more embodiments, the injection mold 340 may include a first electronic element portion 210, a second electronic element portion 220, and a third electronic element portion 230. The first electronic element portion 210, the second electronic element portion 220, and the third electronic element portion 230 may be spaced apart from the side housing 341, and each may have the electronic element 211 corresponding to respective buttons (e.g., the plurality of buttons 350 of FIG. 2A), that is, the sound increase button 351, the sound decrease button 352, and the power button 353, on the side surface 311c of the housing 310.

According to one or more embodiments, the first electronic element portion 210 may include the first electronic element 211, a first mounting part 212, first plated wiring 213, and a first via hole 215, the second electronic element portion 220 may include the second electronic element 221, a second mounting part 222, second plated wiring 223, and a second via hole 225, and the third electronic element portion 230 may include the third electronic element 231, a third mounting part 232, third plated wiring 233, and a third via hole 235.

According to one or more embodiments, the description of the first electronic element portion 210 and the components included by the first electronic element portion 210 may apply to the second electronic element portion 220 and the third electronic element portion 230 as it is or may be applied after a design change in the scope easily understood by those skilled in the art.

Hereinafter, for ease of description, ordinals are omitted, and the components are referred to as “the electronic element 211”, “the mounting part 212”, “the plated wiring 213”, and “the via hole 215”. This also applies to the second electronic element portion 220, the third electronic element portion 230, or more electronic element portions unless otherwise stated.

According to one or more embodiments, the plated wiring 213 may be plated and deposited on the injection mold 340 on the side housing 341, and the electronic element 211 may be mounted to the injection mold 340 on the side housing 341, and may be connected electrically to the plated wiring 213. According to one or more embodiments, the side housing 341 may include the mounting part 212 to which the electronic element 211 is mounted.

The plated wiring 213 may be formed by being deposited on at least one of the outer side surface 341b and inner side surface 341a of the side housing 341 and the first surface 342a and second surface 342b opposite thereto of the flat housing 342. The electronic element 211 may be mounted to the first surface 342a or second surface 342b of the flat housing 342 or to the outer side surface 341b or inner side surface 341a of the side housing 341. The electronic element 211 may be soldered on the plated wiring 213 on the mounting part 212 in the injection mold 340.

According to one or more embodiments, the via hole 215 may be coated with the plated wiring 213. According to one or more embodiments, the via hole 215 may be formed through the first surface 342a and second surface 342b of the flat housing 342 or may be formed through the outer side surface 341b and inner side surface 341a of the side housing 341.

According to one or more embodiments, the via hole 215 and the mounting part 212 may be formed during a molding process of the injection mold 340. In this case, in a mass production process, the uniformity of the shape and position of the via hole 215 and the mounting part 212 may be maintained, and, as a result, a manufacturing yield of the electronic device 301 may be improved. However, example embodiments are not limited thereto, and, in an embodiment, the via hole 215 and the mounting part 212 may be formed through a separate perforating or patterning process after the formation of the injection mold 340. According to one or more embodiments, the size of the mounting part 212 may be designed greater than that of the electronic element 211 considering the size of the electronic element 211. The length of a long axis of the mounting part 212 may be 1.2 times longer than the length of a long axis of the electronic element 211.

FIG. 5 is a cross-sectional view of a partial region of the electronic device (e.g., the electronic device 301 of FIG. 3) according to one or more embodiments.

FIG. 5 is a side cross-sectional view illustrating a coupling structure of the electronic element portion 210 illustrated in FIG. 4C. Referring to FIG. 5, in the electronic device 301 according to one or more embodiments, the electronic element 211 may be mounted directly to the injection mold 340.

According to one or more embodiments, the electronic element 211 may be mounted to the outer side surface 341b of the side housing 341 in the injection mold 340, and the injection mold 340 may be connected electrically to another component, for example, a processor (e.g., the processor 120 of FIG. 1), in the flat housing 342 of the injection mold 340 and the electronic element 211 through the via hole 215 communicating the inner side surface 341a with the outer side surface 341b. A case 345 may be coupled to the outer side surface 341b of the side housing 341. The case 345 may be a part where a user of the electronic device 301 grips the electronic device 301 and may be an outer housing protecting internal components and the electronic element portion 210 inside the case 345.

According to one or more embodiments, as illustrated in FIG. 5, an opening may be formed in a position corresponding to the electronic element 211 in the case 345. A button (e.g., the plurality of buttons 350 of FIG. 2A), for example, the sound increase button 351, the sound decrease button 352, or the power button 353, may be coupled to the opening of the case 345, and the electronic element 211 may receive an input from each button 350 and may relay an electrical signal to the inner side surface 341a of the injection mold 340 through the plated wiring 213.

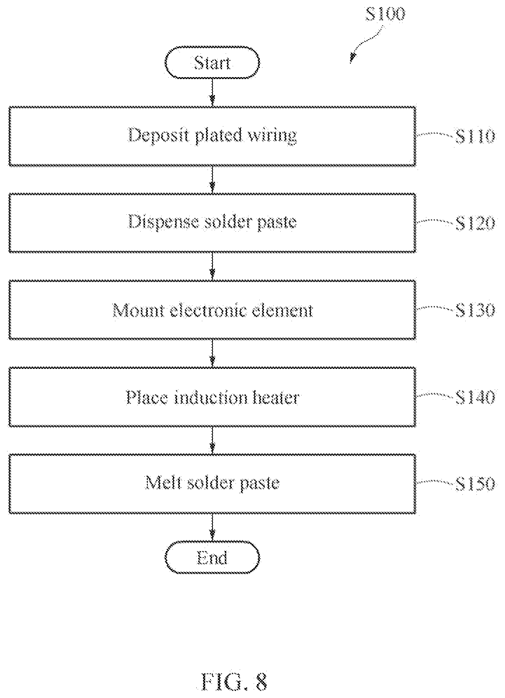

According to one or more embodiments, the injection mold 340 may include a curved region 347 forming a curved structure to be connected to the side surface housing 341 from the flat housing 342. The injection mold 340 having the curved region 347 may be referred to as a 2.5D or 3D injection mold 340 compared with a PCB having a flat structure. According to one or more embodiments, the injection mold 340 may mount the electronic element 211 to the curved region 347 to a stereoscopic structure through a manufacturing method (e.g., a manufacturing method S100 of FIG. 8) to be described later. The electronic element 211 may be mounted to a partial curved region 347.

According to one or more embodiments, the mounting part 212 may be in the injection mold 340. The mounting part 212 may include an element mounting part 212a to which the electronic element 211 is mounted and a wire mounting part 212b to which the plated wiring 213 is mounted. The element mounting part 212a may have a shape and a size corresponding to the shape and size of the electronic element 211 such that the electronic element 211 is mounted directly to the injection mold 340 and is supported. The wire mounting part 212b may be formed at least a portion of a position on which the plated wiring 213 is deposited and, as illustrated in FIG. 5, may be formed limitedly in the element mounting part 212a.

According to one or more embodiments, the electronic element 211 may be mounted to the mounting part 212 formed in the outer side surface 341b of the side housing 341 and may be connected electrically to the plated wiring 213. The plated wiring 213 may be connected to the inner side surface 341a of the side housing 341 of the injection mold 340 through the via hole 215 and may be further connected electrically to the flat housing 342 of the injection mold 340 or an internal component of the electronic device 301. The electronic element 211 may transmit and receive a signal to the inside of the electronic device 301 through the plated wiring 213.

For example, a PCB (e.g., the PCB 451 of FIG. 3) may be positioned in the flat housing 342 of the injection mold 340. In addition, at least one internal component of a processor (e.g., the processor 120 of FIG. 1), a memory (e.g., the memory 130 of FIG. 1), and a communication module (e.g., the communication module 190 of FIG. 1) may be mounted directly to the injection mold 340, or wiring therethrough may be formed in the injection mold 340. In this case, the electronic element 211 may be mounted to the side housing 341 of the injection mold 340 and may be connected to the flat housing 342 through the plated wiring 213 and may be connected electrically to an internal circuitry to another component inside the electronic device 301.

According to one or more embodiments, the side housing 341 of the injection mold 340 to which the electronic element 211 is mounted, a height h1 required when mounting the electronic element 211 may be the height h1 from a mounted surface of the electronic element 211 from the element mounting part 212a or the wire mounting part 212b, to an outer surface of the injection mold 340 of the electronic device 301 to an outer circumferential surface of an edge of the side housing 341 or the case 345 in a perpendicular direction to the mounted surface. When the electronic element 211 is mounted to a separate PCB and the PCB is coupled to the injection mold 340, the height h1 required when mounting the electronic element 211 may increase by the height of the PCB. However, the electronic device 301 according to one or more embodiments may minimize the height h1 required when mounting the electronic element 211 through direct mounting and may improve the efficiency of securing an internal space of the electronic device 301.

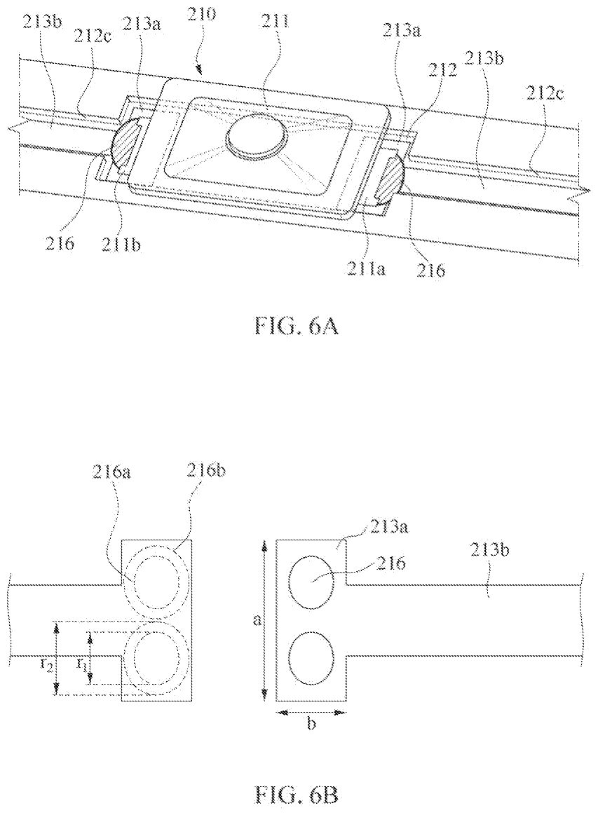

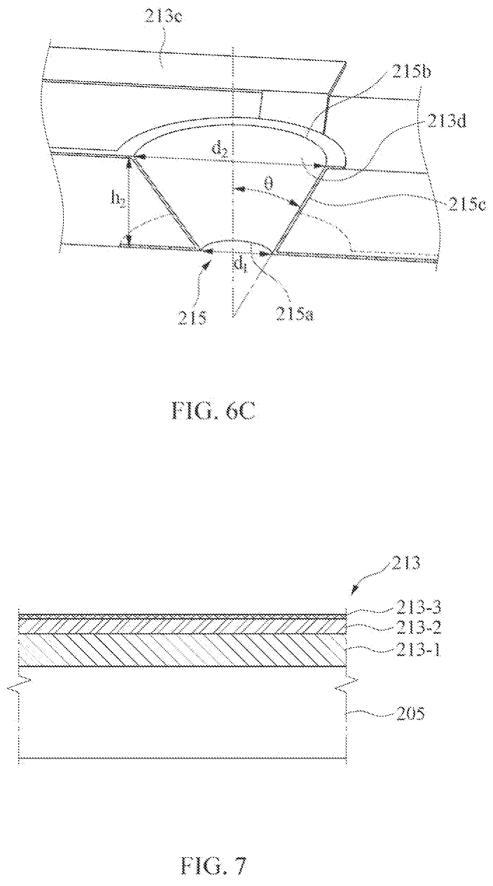

FIG. 6A is an expanded perspective view of the electronic device 301 according to one or more embodiments, FIG. 6B is a plan view of the electronic device 301 according to one or more embodiments, and FIG. 6C is another expanded perspective view of the electronic device 301 according to one or more embodiments.

Referring to FIG. 6A, FIG. 6B, and FIG. 6C, the plated wiring 213 according to one or more embodiments may include a first region 213a, a second region 213b, a third region 213c, and a fourth region 213d, and the via hole 215 may include a first opening 215a, a second opening 215b, and an inner surface 215c.

According to one or more embodiments, the plated wiring 213 may include the first region 213a to which the electronic element 211 is mounted, the second region 213b adjacent to the first region 213a, and the third region 213c farther from the first region 213a than the second region 213b.

According to one or more embodiments, the first region 213a may have a shape corresponding to the shape of terminals 211a and 211b of the electronic element 211 such that the electronic element 211 is mounted. The electronic element 211 may include a first terminal 211a that is on the left side of the electronic element 211 and a second terminal 211b that is on the right side of the electronic element 211 and spaced apart from the first terminal 211a. The plated wiring 213 may have a structure and shape contactable with each of the first terminal 211a and the second terminal 211b of the electronic element 211.

According to one or more embodiments, a vertical length a and a horizontal length b of the first region 213a may be designed based on the vertical and horizontal lengths of the first terminal 211a and the second terminal 211b. The first region 213a may have the vertical length a that is a 120% greater than the vertical length of the first terminal 211a and the horizontal length b that is a 200% greater than the horizontal length of the first terminal 211a, but embodiments are not limited thereto. According to one or more embodiments, the vertical length (that is, a width) of the second region 213b may be 30% to 50% of the vertical length a of the first region 213a or may be set based on the size of the mounting part 212.

According to one or more embodiments, a wiring groove 212c may be formed on the injection mold 340 or the side housing 341, and at least a portion of the plated wiring 213 may be deposited to the wiring groove 212c. According to one or more embodiments, the wiring groove 212c may include a wire mounting part (e.g., the wire mounting part 212b of FIG. 5. According to one or more embodiments, the wiring groove 212c may be formed in a structure preset in a mold injection process of the injection mold 340. Alternatively, the wiring groove 212c may be formed through overlapping laser processing or non-overlapping laser processing, for example, laser direct structuring (LDS) processing, laser manufacturing antenna (LMA) processing, or coated laser manufacturing conductor (C-LMC) processing, in an injection mold.

According to one or more embodiments, a solder paste 216 may be dispensed on the first region 213a of the plated wiring 213, the terminals 211a and 211b of the electronic element 211 may be placed thereon, and the electronic element 211 may be mounted directly to the first region 213a through induction heating. The soldering structure of the electronic element 211 is described in detail below with reference to FIG. 8 and thereafter.

As illustrated in FIG. 6B, the solder paste 216 may be dispensed on the first region 213a of the plated wiring 213, and a dispensing amount of the solder paste 216 may be adjusted variously. As described in detail with reference to FIG. 8 and thereafter, induction heating may be performed on a plurality of solder pastes 216 dispensed on the injection mold 340 individually, and an induction heater (e.g., an induction heater 250 of FIG. 8) may heat the solder paste 216 based on an amount of the solder paste 216. Therefore, in the injection mold 340 according to one or more embodiments, dispensing amounts of the plurality of solder pastes 216 may vary such that various electronic elements 211 may be mounted directly to the injection mold 340 with increased precision and stability.

According to one or more embodiments, the first region 213a may be a region where the terminals 211a and 211b of the electronic element 211 are mounted and may have a polygonal structure based on the structure of the terminals 211a and 211b. According to one or more embodiments, the first region 213a may have a rectangular structure having the vertical length a and the horizontal length b. A solder paste may be dispensed at least once on the first region 213a corresponding to one of the terminals 211a and 211b of the electronic element 211 and may be dispensed at least twice in a direction of the vertical length a as illustrated in FIG. 6B.

According to one or more embodiments, the solder paste 216 may be dispensed in a plane direction (e.g., the X-Y plane or Y-Z plane of FIG. 4) so as to be circular and the solder paste 216 may have a polygonal structure. According to one or more embodiments, the solder paste 216 is dispensed in a circular form, an amount of the solder paste 216 dispensed at once may be calculated based on a diameter of the solder paste 216 and may be controlled. For example, a solder paste 216a according to an embodiment may be dispensed in a diameter r1 that is 80% to 90% of the vertical length a of the first region 213a. For another example, a solder paste 216b may be dispensed to have substantially the same diameter r2 as the vertical length a of the first region 213a. According to one or more embodiments, the solder paste 216 may be dispensed in a diameter range of the 80% to 100% of the vertical length a of the first region 213a selectively depending on the electronic element 211 or may be dispensed based on the horizontal length b of the first region 213a.

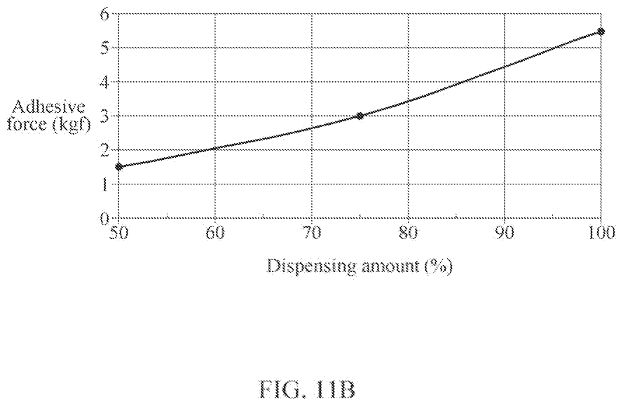

According to one or more embodiments, the electronic device 301 may vary a dispensing amount of the solder paste 216, based on at least one factor among various factors including, but not limited to, the type of the electronic element 211, the size of the terminals 211a and 211b, a composition ratio of the solder paste 216, a manufacturing environment of the electronic device 301, and an operating environment of the electronic device 301. The dispensing amount of the solder paste 216 is described in detail below with reference to the graph of FIG. 11B.

According to one or more embodiments, the second region 213b may be extended from the first region 213a and may be relatively more adjacent to the first region 213a compared to the third region 213c. The width of the plated wiring 213 is relatively greater in the second region 213b than in the third region 213c. The electronic element 211 may receive power, operate, and dissipate heat. According to one or more embodiments, the second region 213b may be designed to have a relatively wide width to receive the heat dissipated from the electronic element 211 and dissipate the heat to the outside and may be designed to have various structures to maximize a surface area to be advantageous for heat dissipation. Through the heat dissipation of the second region 213b, a partial region of a side surface of the electronic device 301 may be prevented from overheating, and problems, such as the melting of the solder paste 216 or the deviation of the electronic element 211, may be prevented in advance.

According to one or more embodiments, the third region 213c may be extended from the second region 213b and may be connected to the via hole 215. The fourth region 213d may be plated to cover the inner surface 215c of the via hole 215. The plated wiring 213 may pass through the injection mold 340 through the via hole 215 and relay an electrical signal or power. According to one or more embodiments, the via hole 215 may communicate from a surface of the injection mold 340 to the other surface that is opposite to the surface. According to one or more embodiments, the plated wiring 213 may be deposited to be electrically continuous from the surface of the injection mold 340 from the outer side surface 341b of the side housing 341, through the via hole 215 to the other surface of the injection mold 340 and to the inner side surface 341a of the side housing 341. According to one or more embodiments, the via hole 215 may include the first opening 215a that is formed on the surface of the injection mold 340 and the second opening 215b that is formed on the other surface of the injection mold 340.

According to one or more embodiments, the cross-sectional area of the inner surface 215c of the via hole 215 may increase in a direction of a height h2 from the first opening 215a to the second opening 215b, that is, from the surface to the other surface of the injection mold 340. A diameter d1 of the first opening 215a may be different from a diameter d2 of the second opening 215b and the width of an opening may gradually decrease or increase in a direction of a height h2 of the via hole 215 from the first opening 215a to the second opening 215b. In this case, when an increase rate of the cross-sectional area of the via hole 215 is constant, the inner surface 215c of the via hole 215 may be slanted at a preset angle θ from the central axis of the via hole 215. The preset angle θ may have an angle within a range of 20 to 40 degrees and may preferably be 30 degrees according to one or more embodiments, the via hole 215 may have various advantages with the inner surface 215c having a slanted form at the preset angle θ.

For example, a separate circuit element may be coupled to the via hole 215, and the via hole 215 may support the circuit element with relatively increased stability when having the slanted form compared to having a non-slanted form and may support the circuit element not to be deviated from the via hole 215. Alternatively, in a coating or deposition process of the fourth region 213d in the inner surface 215c of the plated wiring 213, the via hole 215 may perform plating in one direction and may apply the plating stably to the inner surface of the via hole 215 and may readily form the fourth region 213d of the plated wiring 213.

FIG. 7 is a cross-sectional view of the plated wiring 213 according to one or more embodiments.

Referring to FIG. 7, the plated wiring 213 according to one or more embodiments may have a multilayer structure.

According to one or more embodiments, the plated wiring 213 may have a multilayer structure including at least two layers, for example, a first layer 213-1, a second layer 213-2, and a third layer 213-3. The plated wiring 213 may be deposited to an injection mold 205 (or the injection mold 340 of FIGS. 3 to 5), in which single layers may be deposited sequentially or a multilayer may be deposited at the same time according to a pre-formed structure.

According to one or more embodiments, the first layer 213-1 and the second layer 213-2 of the plated wiring 213 may be formed of a metal material excellent in electrical conductivity or magnetic inducibility. For example, the plated wiring 213 may include the first layer 213-1 formed of copper (Cu) and the second layer 213-2 formed of nickel (Ni). According to one or more embodiments, the plated wiring 213 of a portable electronic device 301, such as a smartphone, may have a total height of 10 to 15 μm. For example, the first layer 213-1 may be 8 to 12 μm and the second layer 213-2 may be 1 to 3 μm.

According to one or more embodiments, the plated wiring 213 may further include a third layer coated on the upper surface of the second layer 213-2, and the third layer 213-3, which is a top layer, may be thinly coated with gold (Au) or nickel (Ni) or an alloy including some of gold (Au) and nickel (Ni). A solder paste (e.g., the solder paste 216 of FIG. 6A) may be dispensed on an upper portion of the third layer 213-3, which is the top layer, and the third layer 213-1 may be formed of a material that is suitable for maintaining the shape of the dispensed solder paste 216 and controlling solder spreadability.

According to one or more embodiments, the spreadability of the solder paste 216 may be a degree of the dispensed solder paste 216 being melted and spreading across the plated wiring 213 as induction heating is performed, and, when the spreadability is high, the solder paste 216 may have little surface tension and may be applied evenly to the plated wiring 213.

According to one or more embodiments, the plated wiring 213, of which the top layer is formed of gold (Au) or nickel (Ni), may have little surface tension with the solder paste 216 compared to other types of metal. With the plated wiring 213 having good spreadability, a non-soldering or insufficient soldering problem of the electronic element 211 may be prevented and soldering may be performed stably.

According to one or more embodiments, the third layer 213-3 formed of gold (Au) may have the advantageous effect of controlling the spreadability of the solder paste 216 precisely compared to other metal materials. The third layer 213-3, which is the top layer, may be a thin film having a thickness between 0.01 to 0.05 μm. In this case, the plated wiring 213 may perform the plating of the top layer with gold (Au) on the whole wiring of a mold direct mount (MDM) method, which is a method of direct mounting to wiring for an antenna.

According to one or more embodiments, the plated wiring 213 formed of nickel (Ni) including the third layer 213-3 or including the first layer 213-1 and the second layer 213-2 without including the third layer 213-3, in which the second layer 213-2 is the top layer, may be economical and may have high magnetic inducibility compared one or more embodiments including gold (Au). A method of manufacturing the electronic device 301 may control a state of the plated wiring 213 such that an oxide film may not be formed on the third layer 213-3 to control the spreadability of the solder paste 216.

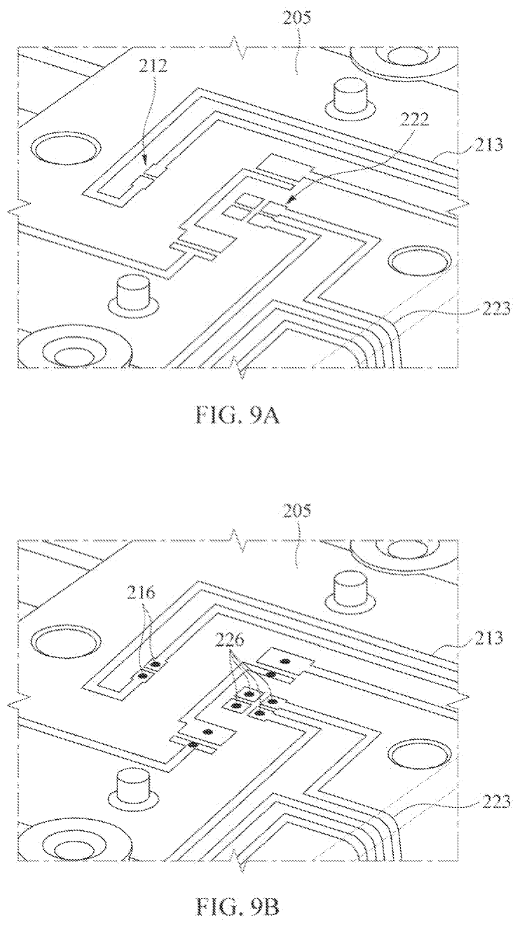

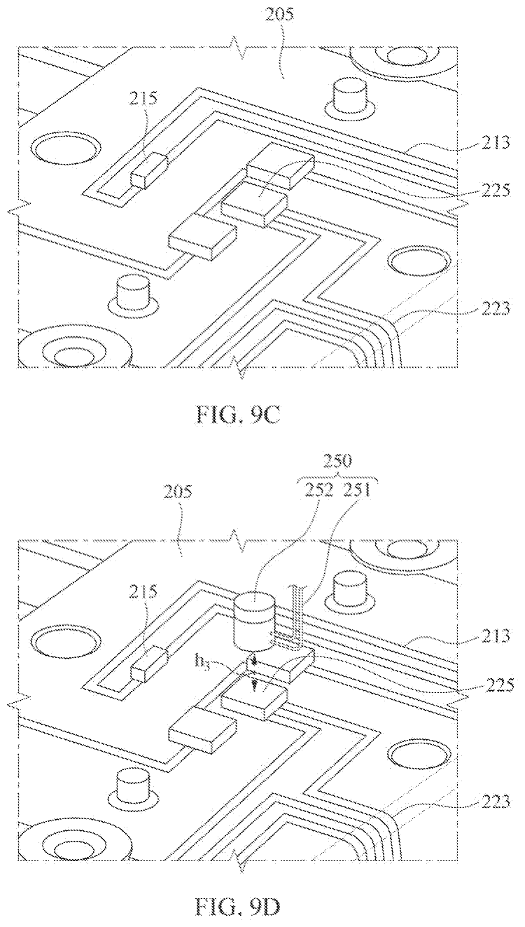

FIG. 8 is a flowchart of a method of manufacturing the electronic device 301 according to one or more embodiments, and FIG. 9A, FIG. 9B, FIG. 9C and FIG. 9D are diagrams each illustrating a manufacturing operation of the method of manufacturing the electronic device according to one or more embodiments.

FIG. 9A is a diagram illustrating operation S110 of depositing the plated wiring 213 on the injection mold 340 in a laser plating method, FIG. 9B is a diagram illustrating operation S120 of dispensing the solder paste 216 on the plated wiring 213, FIG. 9C is a diagram illustrating operation S130 of mounting the electronic element 211 to the solder paste 216, and FIG. 9D is a diagram illustrating operation S140 of placing the induction heater 250 configured to heat the solder paste 216 adjacent to the electronic element 211 and operation S150 of melting the solder paste 216 through the induction heater 250 to mount the electronic element 211 substantially directly to the injection mold 340.

Hereinafter, a repeated description of the components included in the electronic device 301 is omitted or summarized when providing the description of the method of manufacturing the electronic device 301.

Referring to FIG. 8, the method of manufacturing the electronic device 301 may include operation S140 of placing the induction heater 250 (refer to FIG. 9D) adjacent to the electronic element 211 and operation S150 of melting the solder paste 216 through the induction heater 250 to mount the electronic element 211 directly to the injection mold 340.

According to one or more embodiments, at least some operations of the method of manufacturing the electronic device 301 may be implemented while each operation is performed by a program of a manufacturing device of the electronic device 301, and the program may be implemented as a program including an algorithm executable in a computer. The program including the algorithm may be provided by being stored in a non-transitory computer readable medium. The non-transitory computer readable medium may not be a medium, such as register, cache, or memory, storing data for a short moment but may be a medium storing data semi-permanently and readable by a device. Programs for performing various methods described above may be provided by being stored in the non-transitory computer readable medium, such as a CD, a digital video/versatile disc (DVD) a hard disc, a Blu-ray disc, a universal serial bus (USB), a memory card, or a read-only memory (ROM).

According to one or more embodiments, the method S100 of manufacturing the electronic device 301 may include operation S110 of depositing the plated wiring 213 on the injection mold 340 in the laser plating method (refer to FIG. 9A).

According to one or more embodiments, the plated wiring 213 may have a multilayer structure and a metal material forming each layer may be deposited at a preset position on the injection mold 340 through laser processing. After performing overlapping or non-overlapping laser processing on the injection mold 340 by using a trench-fill method, the plated wiring 213 may be formed by performing a plating operation thereon for filling.

According to one or more embodiments, the method of forming the plated wiring 213 is not limited, and the plated wiring 213 may be stacked through LDS processing, LMA processing, or C-LMC processing. According to one or more embodiments, the plated wiring 213 may be processed in a method of depositing the plated wiring 213 on the injection mold 340 by passing the plated wiring 213 through a chamber including a metal material in a molten state or by coating a thin film formed of a metal material on the injection mold 340.

According to one or more embodiments, the injection mold 340 may have a 2.5D or 3D stereoscopic structure, and the plated wiring 213 may be plated on the stereoscopic structure to be connected continuously from one surface to the other surface. The plated wiring 213 may include the first plated wiring 213 corresponding to a first electronic element 211 in the first mounting part 212 where the first electronic element 211 is mounted and the second plated wiring 223 corresponding to a second electronic element 221 in the second mounting part 222 where the second electronic element 221 is mounted. Referring to FIG. 9A, the second plated wiring 223 may be connected continuously from one surface to the other surface of a stereoscopic injection mold 340.

According to one or more embodiments, the method S100 of manufacturing the electronic device 301 may include operation S120 of dispensing the solder paste 216 on the plated wiring 213 (refer to FIG. 9B) and may include operation S130 of mounting the electronic element 211 to the solder paste 216 (refer to FIG. 9C). The electronic device 301 may dispense the solder paste 216 on the injection mold 340 and may mount the electronic element 211 thereon such that the electronic element 211 may have a structure of being mounted directly to the injection mold 340. This direct mounting structure may be referred to as MDM.

The electronic device 301 according to an embodiment, compared to a mounting method including a PCB, may secure an inner space through a structure mounted directly on the injection mold 340, and another component may be mounted in the secured space. For example, a space that may be occupied by a main processor (e.g., the processor 120 of FIG. 1) of the electronic device 301 or a battery (e.g., the battery 189 of FIG. 1) of the electronic device 301 may be secured, which may improve a usage time or performance of the electronic device 301.

According to one or more embodiments, the method S100 of manufacturing the electronic device 301 may include operation S140 of placing the induction heater 250 for heating the solder paste 216 adjacent to the electronic element 211 and may include operation S150 of melting the solder paste 216 through the induction heater 250 to mount the electronic element 211 substantially directly to the injection mold 340 (refer to FIG. 9D). The induction heater 250 may include a coil 251 and a heating region 252 and the heating region 252 may be implemented as ferrite wrapped by the coil 251.

According to one or more embodiments, the heating region 252 may be spaced apart at a preset distance h3 from the electronic element 211. If the distance h3 from the heating region 252 to the electronic element 211 is close, the time and power spent for induction heating may be reduced and production efficiency may be improved.

According to one or more embodiments, when an area of the solder paste 216 to be heated is large, or the electronic element 211 is vulnerable to a high temperature, the distance h3 from the heating region 252 to the electronic element 211 may be set to increase. The method of manufacturing the electronic device 301 according to one or more embodiments may set the distance h3 between the heating region 252 and the electronic element 211 to individually vary according to various factors of the solder paste 216 and the electronic element 211.

According to one or more embodiments, the coil 251 may receive power and the heating region 252 may form a magnetic field and may inductively heat the solder paste 216. The coil 251 may have a pipe shape inside which a flow path is formed, and a cooling water may flow into the coil 251 and may cool the coil 251 so as not to overheat the coil 251 and the heating region 252.

According to one or more embodiments, the induction heater 250 may generate a high frequency output in a 1 to 12 KW range and may cover a frequency band of 100 to 400 KHz. The induction heater 250 may optimize the shape, external diameter, internal diameter, internal cooling performance, and winding number of the coil 251 or a structure of the heating region 252, based on an output range, a plating thickness in the electronic element 211, a structure of the injection mold 340, and a structure of a jig supporting the injection mold 340.

According to one or more embodiments, some of a plurality of electronic elements 211 may be mounted to another plane or another height on the injection mold 340 having a 3D structure. In this case, the method S100 of manufacturing the electronic device 301, prior to operation S140 of placing the induction heater 250 adjacent to the electronic element 211, may rotate the injection mold 340 such that the induction heater 250 may face the electronic element 211 or may change a direction of the heating region 252 such that the induction heater 250 may face the other surface of the injection mold 340.

According to one or more embodiments, the method S100 of manufacturing the electronic device 301 may mount the electronic element 211 directly to various positions of the injection mold 340 having a 3D structure and may have a manufacturing advantage by simplifying a process for mounting the electronic element 211 to the 3D injection mold 340.

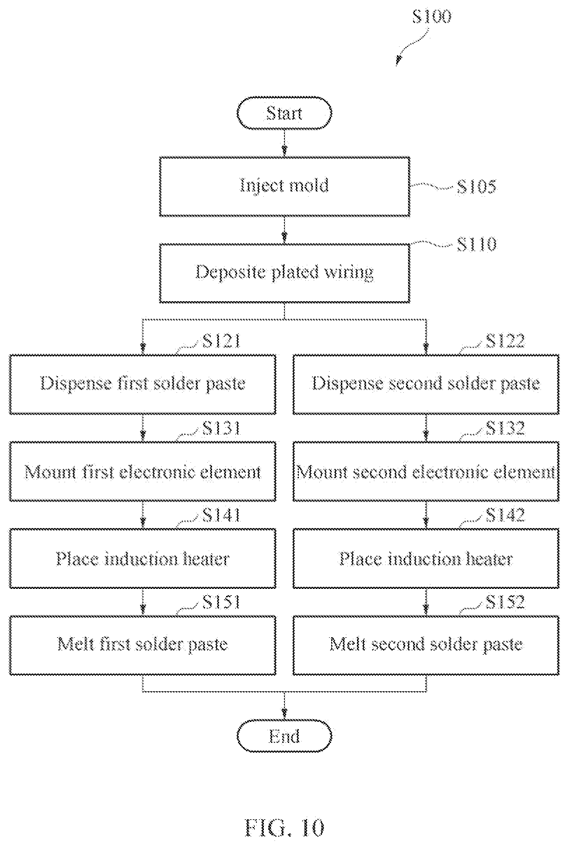

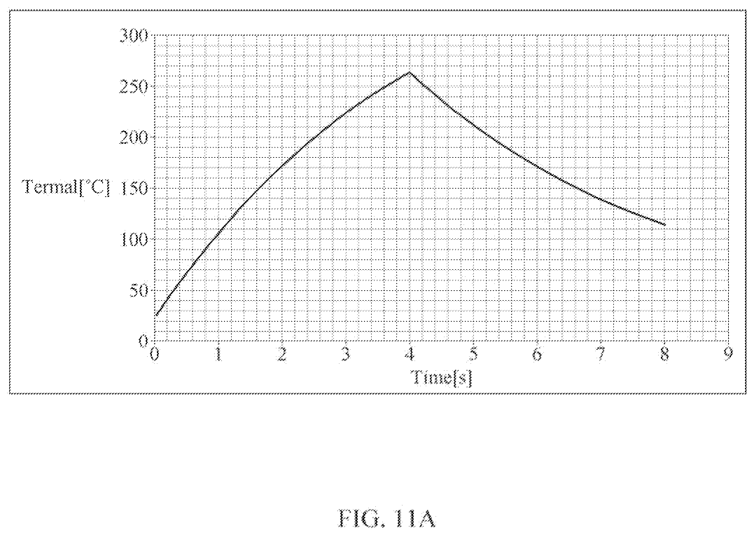

FIG. 10 is another flowchart of the method of manufacturing the electronic device 301 according to one or more embodiments.

According to one or more embodiments, the method S100 of manufacturing the electronic device 301 may include operation S105 of forming the injection mold 340 by injecting a mold. A material of the injection mold 340 may not be limited and may be formed of, for example, a polycarbonates (PC) material, a polyphenylene sulfide (PPS) material, or an LDS resin material. The injection mold 340 may be designed by securing the mounting part 212 of the electronic element 211 in a mold design stage and may be designed by securing the via hole 215. The injection mold 340 may be injected by including the mounting part 212 or the via hole 215 through mold injection. Thus, a perforating or patterning operation may be omitted, a mass production may be readily performed, and a manufacturing yield may be improved.

According to one or more embodiments, the method S100 of manufacturing the electronic device 301 may include operation S121 of dispensing the first solder paste 216 with a preset discharge amount on the plated wiring 213 that is in the first mounting part 212 in the injection mold 340 and operation S122 of dispensing the second solder paste 226 with a preset discharge amount on the plated wiring 223 that is in the second mounting part 222 in the injection mold 340. In addition, according to one or more embodiments, the method S100 of manufacturing the electronic device 301 may include operation S131 of mounting the first electronic element 211 to the first solder paste 216 and operation S132 of mounting the second electronic element 221 to the second solder paste 226.

According to one or more embodiments, a dispensing amount of the first solder paste 216 may be different from a preset discharge amount of the second solder paste 226. In the method S100 of manufacturing the electronic device 301, because each of the electronic elements 211 and 221 is directly mounted through induction heating, a dispensing amount of the first solder paste 216 and the second solder paste 226 may be designed variously based on various factors, such as the shape, arrangement, and structure of the injection mold 340, the first electronic element 211, and the second electronic element 221, the non-soldering, insufficient soldering, or excessive soldering of the solder pastes 216 and 226 may be prevented, and the first electronic element 211 and the second electronic element 221 may be mounted with increased precision and stability.

According to one or more embodiments, the number of dispensing the first solder paste 216 may be different from the number of dispensing the second solder paste 226. According to one or more embodiments, the method S100 of manufacturing the electronic element 211 may adjust the number of dispensing based on a structure of the electronic element 211 and the terminals 211a and 211b thereof. The number of dispensing may be a simply repeated dispensing operation at the same position in the same mounting part 212 or may be the plural number of dispensing by varying a position of the solder paste 216 in the mounting part 212.

As illustrated in FIG. 6A, when the terminals 211a and 211b have a structure having a long axis and a short axis, the solder paste 216 may be dispensed at least twice in a long axis direction. According to one or more embodiments, the method S100 of manufacturing the electronic element 211 may variously design the number of dispensing the first solder paste 216 and the second solder paste 226 based on various factors, such as the shape, arrangement, and structure of the injection mold 340, the first electronic element 211, and the second electronic element 221, may prevent non-soldering, insufficient soldering, or excessive soldering of the solder paste 216, and may mount the first electronic element 211 and the second electronic element 221 with increased precision and stability.

According to one or more embodiments, the method S100 of manufacturing the electronic device 301 may include operation S141 of placing the induction heater 250 adjacent to the first electronic element 221 and operation S142 of placing the induction heater 250 adjacent to the second electronic element 221. According to one or more embodiments, in the method S100 of manufacturing the electronic device 301, one induction heater 250 may be placed while sequentially moving to the first electronic element 211 and the second electronic element 221, or a plurality of induction heaters 250 may be placed respectively in the first electronic element 211 and the second electronic element 221.

According to one or more embodiments, the method S100 of manufacturing the electronic device 301 may include operation S151 of melting the first solder paste 216 and operation S152 of melting the second solder paste 226. In this case, each of melting operations S151 and S152 may be different from each other in at least one of an induction heating time of the induction heater 250, induction heating power of the induction heater 250, and a distance from the solder paste 216 to the induction heater 250.

According to one or more embodiments, the induction heater 250 may adjust the spreadability of the solder paste 216 by adjusting factors including, but not limited to, an induction heating time, induction heating power, or a distance spaced apart from the induction heater 250, which heat the solder paste 250. The spreadability of the solder paste 216 may be a degree of the dispensed solder paste 216 being melted and spreading across the plated wiring 213 as induction heating is performed. When the spreadability is low, the solder paste 216 may maintain a dispensed shape, and, when the spreadability is high, the solder paste 216 may flow into the adjacent plated wiring 213 as the height of the solder paste 216 is lowering.

A state in which the solder paste 216 is dispensed may have 0% spreadability, and a state in which the solder paste 216 is inductively heated and spreads to substantially form a flat surface may have 100% spreadability. In this case, it may be appropriate for the solder paste 216 to be inductively heated to have 20% to 40% spreadability for appropriate soldering.

According to one or more embodiments, the first solder paste 216 and the second solder paste 226 may be different in a dispensing amount, the number of dispensing, the thermal resistance of the electronic element 211, and a wiring structure. If the induction heater 250 heats the first solder paste 216 and the second solder paste 226 under the same condition, the spreadability of at least one may be excessive or insufficient. The method S100 of the electronic device 301 herein may control a heating time and heating power of the first solder paste 216 and the second solder paste 226 or a distance from the solder paste 216 through the induction heater 250, may adjust the spreadability of each of the first and second solder pastes 216 and 226 to an appropriate range, and may mount the first electronic element 211 and the second electronic element 221 with increased precision and stability.

FIG. 11A is a profile of a temperature of the solder paste 216 with respect to a time of the method of manufacturing the electronic device 301 according to one or more embodiments.

FIG. 11A is the profile illustrating the temperature of the solder paste 216 from 0 to 8 seconds when the induction heater 250 starts induction heating at 0 seconds and stops the induction heating at 4 seconds in melting operation S150 of the solder paste 216 of the method S100 of manufacturing the electronic device 301 according to one or more embodiments.

Referring to 11A, the induction heater 250 according to one or more embodiments may increase a temperature of one solder paste 216 to greater than or equal to 250 degrees by operating for 4 seconds and may fix the electronic element 211 and connect the electronic element 211 electrically to the plated wiring 213 with the solder paste 216 hardening again after melted around 250 degrees.

The method S100 of the electronic device 301 according to one or more embodiments may skip a process of cooling the whole injection mold 340 after heating the whole injection mold 340 because the induction heater 250 performs soldering while moving adjacent to the solder paste 216.

If the process of cooling the whole injection mold 340 after heating the whole injection mold 340 is included, a time required for soldering may increase because heating is performed at a low temperature for a long time to prevent damage to the plated wiring 213 and other components from heat while the solder paste 216 across the whole injection mold 340 is evenly melted. A chamber and an oven for heating may be required and a space where the whole injection mold 340 may move and perform each process may be secured. In addition, a movement device and a cooling facility for a cooling process may be required to undergo a separate cooling process and a cooling time may be additionally incurred.

The method S100 of the electronic device 301 according to one or more embodiments herein may increase precision and stability by individually heating each of the solder pastes 216 and 226 and may reduce the time and power consumed for soldering of the whole injection mold 340.

According to one or more embodiments, while heating the second solder paste 226 after heating the first solder paste 216, the first solder paste 216 may be cooled. In this case, a separate cooling process may not be required, a processing time may be reduced, a space secured for the movement of the injection mold 340 may be minimized because the induction heater 250 moves, and the maintenance and repair of a manufacturing device may be readily available.

For example, cooling the whole injection mold 340 after heating the whole injection mold 340 to mount three electronic elements 211 may require 3 to 7 minutes. However, the method of manufacturing the electronic device 301 according to an embodiment herein may require only an induction heating time between 3 and 6 seconds per electronic element 211. Thus, the cooling after the heating of the whole injection mold 340 may require less than a total of 1 minute.

The method of manufacturing the electronic device 301 according to an embodiment may perform operations S110 to S150 of FIG. 8 on the injection mold 340 without the need for the injection mold 340 to move to a heating chamber or a cooling chamber, may prevent a crack of soldering caused by a movement process of the injection mold 340, a distortion of an element, and a foreign matter inflow, and may improve a product defect rate by reducing factors of cold soldering or non-soldering.

As described above, since an induction heating process is performed after solder-dispensing based on the characteristics of the electronic element 211 individually, a soldering process may be performed with increased precision and stability.

FIG. 11B is a profile of adhesion with respect to an amount of the solder paste 216 of the method of manufacturing the electronic device 301 according to one or more embodiments.

Specifically, FIG. 11B is a graph illustrating, in operation S120 of dispensing the solder paste 216 in the method S100 of manufacturing the electronic device 301, the adhesion of the solder paste 216 by adjusting a ratio of diameters r1 and r2 of the dispensed solder paste 216 with respect to the vertical length b (refer to FIG. 6B) of the first region 213a of the plated wiring 213 between 50% and 100%.

Referring to FIG. 11A, since the method S100 of manufacturing the electronic device 301 according to one or more embodiments has a structure in which the solder paste 216 is inductively heated individually and mounted directly, various factors (e.g., time, distance, or power) described above may be adjusted stably according to an amount of the solder paste 216 and a soldering process may be performed, and the adhesion of the solder paste 216 may be adjusted by controlling the soldering process precisely.

The method S100 of manufacturing the electronic device 301 according to one or more embodiments may set target adhesion based on various factors, such as the type of the electronic element 211 mounted directly, a mounted position, or a manufacturing or use environment of the electronic device 301, may adjust the amount of the solder paste 216 based on the set target adhesion, may mount the electronic element 211 on the injection mold 340 with increased precision, and may improve the durability of the electronic device 301.

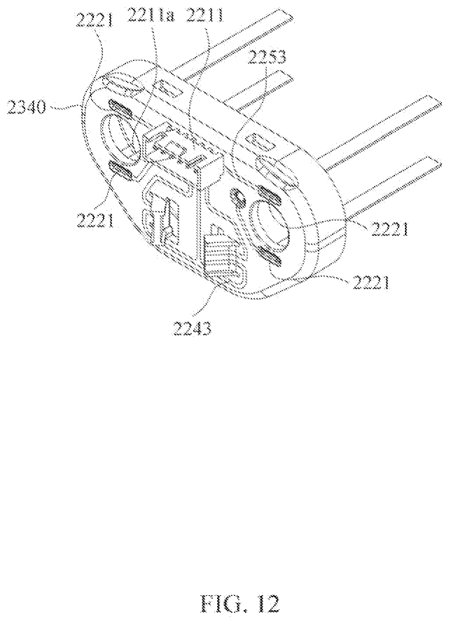

FIG. 12 is a perspective view of an electronic device 2340 according to one or more embodiments.

Although the descriptions above are provided with an example of a portable wireless communication device as an embodiment of an electronic device (e.g., the electronic device 301 of FIG. 2A and subsequent drawings), the electronic device according to an embodiment herein is not limited thereto, and the descriptions may apply to all types of electronic devices requiring a soldering process. For example, the electronic device may be a wearable device, such as a smartwatch or AR glasses, a display device, an electronic appliance, a vehicle component, an LED lamp, a touch panel, an antenna module, a wire, or an FPCB.

Referring to FIG. 12, the electronic device 2340 according to one or more embodiments may be the electronic device 2340 including electronic elements 2211 and 2221 such as, but not limited to, a sensor element, or may be a configuration of an electronic appliance, such as a washing machine or an air conditioner.

Referring to FIG. 12, the electronic device 2340 may include an injection mold, and a first electronic element 2211 and a second electronic element 2221 may be mounted substantially directly to the electronic device 2340.

According to one or more embodiments, the electronic device 2340 may include the first electronic element 2211 connected to an external component including a connector pin 2211a. According to one or more embodiments, the electronic device 2340 may include a plurality of second electronic elements 2221 in a form of terminals connecting the electronic device 2340 to an external component or another electronic device.

According to one or more embodiments, first plated wiring 2253 may be plated on the electronic device 2340 including the injection mold and may connect electrically the first electronic element 2211 to the second electronic element 2221. According to one or more embodiments, second plated wiring 2243 may be wiring connecting the first electronic element 2211 directly to another component. The second plated wiring 2243 may perform as wiring connecting the electronic device 2340 to an external component, such as, but not limited to, an external sensor.

According to one or more embodiments, the first electronic element 2211 and the second electronic element 2221 may be mounted directly on the electronic device 2340 through an MDM technique of the manufacturing method S100 (refer to FIG. 8 or FIG. 10) described above and may be plated on a groove structure in the electronic device 2340 through laser processing.

According to one or more embodiments, as illustrated in FIG. 12, when the electronic device 2340 has a 3D stereoscopic structure, a technique that is not MDM may require separate wiring through which a connection may be performed to the external component. In this case, product defects may occur due to various causes, such as misassembly, wire disconnection, wire twisting, or separation problems, and a sensing error may occur in a sensor. The electronic device 2340 according to one or more embodiments may directly mount the first electronic element 2211 including the connector pin 2211a and the second electronic element 2221 in a terminal form through the MDM technique and may perform soldering with increased precision and stability and may solve product defects.

According to one or more embodiments, the electronic device 301 may include the front plate 311a, the rear plate 311b, the housing 210 including the side housing 341 including an injection mold forming a side surface surrounding a space between the front plate 311a and the rear plate 311b, the plated wiring 213 that is plated on and deposited to the side housing 341, and the electronic element 211 that is mounted to the side housing 341 and connected electrically to the plated wiring 213. According to one or more embodiments, the electronic element 211 may mounted substantially directly to the side housing 341 by the solder paste 216 dispensed on the plated wiring 213.

According to one or more embodiments, the first mounting part 212 and the second mounting part 222 may be formed and spaced apart in the side housing 341. According to one or more embodiments, the electronic elements 211 and 221 may include the first electronic element 211, which is mounted in the first mounting part 212 and is bonded by the first solder paste 216, and may include the second electronic element 221, which is mounted in the second mounting part 222 and is bonded by the second solder paste 226 having spreadability different from that of the first solder paste 216.

According to one or more embodiments, the electronic element 211 may be mounted to the outer side surface 341b of the side housing 341 toward the outside of the electronic device 301. According to one or more embodiments, the side housing 341 may include the via hole 215 communicating from the outer side surface 341b to the inner side surface 341a toward the inside of the electronic device 301. According to one or more embodiments, the plated wiring 213 may be deposited to be connected continuously from the outer side surface 341b through the via hole 215 to the inner side surface 341a.

According to one or more embodiments, the top layer 213-3 of the plated wiring 213 contacting with the solder paste 216 may be formed as a multilayer thinly coated with a metal material. According to one or more embodiments, the metal material may include at least one of gold (Au) and nickel (Ni).

According to one or more embodiments, the plated wiring 213 may include the first region 213a to which the electronic element 211 is mounted, the second region 213b connected to the first region 213a, and the third region 213c at a farther distance from the first region 213a than the second region 213b. According to one or more embodiments, the plated wiring 213 may have a wider width in the second region 213b than in the third region 213c.

According to one or more embodiments, the electronic device 301 may include the injection mold 340 including the mounting part 212 and the wiring groove 212c, the plated wiring 213 plated on the wiring groove 212c, and the electronic element 211 mounted to the mounting part 212 and connected electrically to the plated wiring 213. According to one or more embodiments, the plated wiring 213 may include a structure plated and deposited on an outer region of the injection mold 340, and the electronic element 211 may be mounted substantially directly to the injection mold 340 by the solder paste 216 dispensed on the plated wiring 213.

According to one or more embodiments, the first mounting part 212 and the second mounting part 222 may be formed and spaced apart in the injection mold 340. According to one or more embodiments, the electronic elements 211 and 221 may include the first electronic element 211, which is mounted in the first mounting part 212 and is bonded by the first solder paste 216, and may include the second electronic element 221, which is mounted in the second mounting part 222 and is bonded by the second solder paste 226 having spreadability different from that of the first solder paste 216.

According to one or more embodiments, the top layer 213-3 of the plated wiring 213 contacting with the solder paste 216 may be formed as a multilayer thinly coated with a metal material.

According to one or more embodiments, the metal material of the top layer 213-3 of the plated wiring 213 may include at least one of gold (Au) and nickel (Ni).

According to one or more embodiments, the top layer of plated wire (213) may be a thin film having a thickness between 0.01 μm and 0.05 μm.

According to one or more embodiments, the plated wiring 213 may include the first region 213a to which the electronic element 211 is mounted, the second region 213b connected to the first region 213a, and the third region 213c at a farther distance from the first region 213a than the second region 213b. According to one or more embodiments, the plated wiring 213 may have a wider width in the second region 213b than in the third region 213c.

According to one or more embodiments, the injection mold 340 may have a curved structure in at least a partial region 347. According to one or more embodiments, the electronic element 211 may be mounted to the partial curved region 347.

According to one or more embodiments, the injection mold 340 may communicate from one surface to the other surface that is opposite to the surface and may include the via hole 215 having a cross-sectional area of the inner surface 215c increasing from the surface to the other surface. According to one or more embodiments, the plated wiring 213 may be plated to cover the inner surface of the via hole 215 and may be deposited continuously from the surface to the other surface through the via hole 215.

The method S100 of manufacturing the electronic device 301 may include operation S110 of depositing the plated wiring 213 through laser processing and plating on the injection mold 340, operation S120 of dispensing the solder paste 216 on the plated wiring 213, operation S130 of mounting the electronic element 211 to the solder paste 216, operation S140 of placing the induction heater 250 configured to heat the solder paste 216 adjacent to the electronic element 211, and operation S150 of melting the solder paste 216 through the induction heater 250 to mount the electronic element 211 substantially directly to the injection mold 340.

According to one or more embodiments, prior to operation S140 of placing the induction heater 250 adjacent to the electronic element 211, the method may include rotating the injection mold 340 such that the injection heater 250 faces the electronic element 211.

According to one or more embodiments, operation S120 of dispensing the solder paste 216 on the plated wiring 213 may include operation S121 of dispensing the first solder paste 216 with a preset discharge amount on the plated wiring 213 that is in the first mounting part 212 in the injection mold 340 and operation S122 of dispensing the second solder paste 226 with a preset discharge amount on the plated wiring 223 that is in the second mounting part 222 in the injection mold 340.

According to one or more embodiments, in operation S120 of dispensing the solder paste 216 on the plated wiring 213, the preset discharge amount of the first solder paste 216 may be different from the preset discharge amount of the second solder paste 226.

According to one or more embodiments, in operation S120 of dispensing the solder paste 216 on the plated wiring 213, the number of dispensing the first solder paste 216 may be different from the number of dispensing the second solder paste 226.

According to one or more embodiments, operation S150 of melting the solder paste 216 may include operation S151 of melting the first solder paste 216 and operation S152 of melting the second solder paste 226. According to one or more embodiments, operation S151 of melting the first solder paste and operation S152 of melting the second solder paste may be performed sequentially.

According to one or more embodiments, operation S151 of melting the first solder paste 216 and operation S152 of melting the second solder paste 226 may be different from each other in at least one of an induction heating time of the induction heater 250, induction heating power of the induction heater 250, and a distance from the solder paste 216 to the induction heater 250. Although certain example embodiments are illustrated and described above, the present disclosure is not limited to said certain embodiments, various applications may of course be performed by those skilled in the art without deviating from what is claimed in the scope of claims, and such applications should not be understood separately from the technical idea or prospects herein.

What is claimed is:

1. An electronic device comprising:
an injection mold comprising a mounting part and a wiring groove;
plated wiring plated on the wiring groove; and
an electronic element mounted on the mounting part and connected electrically to the plated wiring,
wherein the plated wiring is plated on an outer region of the injection mold, and
wherein the electronic element is mounted substantially directly on the injection mold by a solder paste dispensed on the plated wiring.

2. The electronic device of claim 1, wherein the injection mold further comprises a first mounting part and a second mounting part that are spaced apart from each other, and
wherein the electronic element comprises:
a first electronic element in the first mounting part and bonded by a first solder paste; and
a second electronic element in the second mounting part and bonded by a second solder paste having a spreadability different from a spreadability of the first solder paste.

3. The electronic device of claim 1, wherein the plated wiring comprises a multilayer that is thin-film coated with a metal material in a top layer of the plated wiring contacting the solder paste.

4. The electronic device of claim 3, wherein the metal material of the top layer of the plated wiring comprises at least one of gold (Au) and nickel (Ni).

5. The electronic device of claim 3, wherein the metal material of the top layer of the plated wiring has a thickness between 0.01 μm and 0.05 μm.

6. The electronic device of claim 1, wherein the plated wiring comprises:
a first region on which the electronic element is mounted;
a second region connected to the first region; and
a third region that is farther from the first region than the second region, and
wherein a width of the plated wiring is wider in the second region than in the third region.

7. The electronic device of claim 1, wherein the injection mold comprises a curved region, and
the electronic element is mounted on the curved region.

8. The electronic device of claim 1, wherein the injection mold communicates from a first surface to a second surface opposite to the first surface and comprises a via hole having a cross-sectional area of an inner surface,
wherein the cross-sectional area increases from the first surface to the second surface, and
wherein the plated wiring covers the inner surface of the via hole and is deposited continuously from the first surface to the second surface through the via hole.

9. A method of manufacturing an electronic device, the method comprising:
depositing plated wiring through laser processing and plating the plated wiring on an injection mold;
dispensing a solder paste on the plated wiring;
mounting an electronic element to the solder paste;
placing an induction heater adjacent to the electronic element; and
melting the solder paste, using the induction heater, to mount the electronic element substantially directly on the injection mold.

10. The method of claim 9, further comprising:
prior to the placing the induction heater adjacent to the electronic element,
rotating the injection mold such that the injection heater faces the electronic element.

11. The method of claim 9, wherein the injection mold comprises a first mounting part and a second mounting part, and
wherein the dispensing the solder paste on the plated wiring comprises:
dispensing a first solder paste with a preset discharge amount on the first mounting part; and
dispensing a second solder paste with a preset discharge amount on the second mounting part.

12. The method of claim 11, wherein the preset discharge amount of the first solder paste is different from the preset discharge amount of the second solder paste.

13. The method of claim 11, wherein the amount of the first solder paste dispensed is different from the amount of the second solder paste dispensed.

14. The method of claim 11, wherein the melting the solder paste comprises:
melting the first solder paste; and
melting the second solder paste, and
wherein the melting of the first solder paste and the melting of the second solder paste are performed sequentially.

15. The method of claim 14, wherein the melting of the first solder paste and the melting of the second solder paste are different from each other in at least one of an induction heating time of the induction heater, induction heating power of the induction heater, and a distance from the solder paste to the induction heater.

16. An electronic device comprising:
a housing including a front plate, a rear plate, and a side housing comprising an injection mold forming a side surface surrounding a space between the front plate and the rear plate,
a plated wiring plated on the side housing, and
an electronic element mounted to the side housing and connected electrically to the plated wiring,
wherein the electronic element mounted substantially directly to the side housing by the solder paste dispensed on the plated wiring.

17. The electronic device of claim 16, wherein the injection mold further comprises a first mounting part and a second mounting part that are spaced apart from each other, and
wherein the electronic element comprises:
a first electronic element in the first mounting part and bonded by a first solder paste; and
a second electronic element in the second mounting part and bonded by a second solder paste having a spreadability different from a spreadability of the first solder paste.

18. The electronic device of claim 16,
wherein the electronic element is mounted to an outer side surface of the side housing toward an outside of the electronic device,
wherein the side housing comprises a via hole communicating from the outer side surface to an inner side surface of the side housing toward an inside of the electronic device, and
wherein the plated wiring is deposited continuously from the outer side surface through the via hole to the inner side surface.

19. The electronic device of claim 16,
wherein the plated wiring comprises a multilayer that is thin-film coated with a metal material in a top layer of the plated wiring contacting the solder paste, and
wherein the metal material of the top layer of the plated wiring comprises at least one of gold (Au) and nickel (Ni).

20. The electronic device of claim 16, wherein the plated wiring comprises:
a first region on which the electronic element is mounted;
a second region connected to the first region; and
a third region that is farther from the first region than the second region, and
wherein a width of the plated wiring is wider in the second region than in the third region.
